(19) United States
(12) Patent Application Publication
(10) Pub. No.: US 2013/0240868 A1
(43) Pub. Date: Sep. 19, 2013

(54) ANTHRACENE DERIVATIVE COMPOUNDS FOR ELECTRONIC APPLICATIONS

(71) Applicants: Kerwin D. Dobbs, Wilmington, DE (US); Weiying Gao, Landenberg, PA (US); Norman Herron, Newark, DE (US); Vsevolod Rostovtsev, Swarthmore, PA (US); Weishi Wu, Landenberg, PA (US); Yulong Shen, Plano, TX (US); Hong Meng, Wilmiington, DE (US)

(72) Inventors: Kerwin D. Dobbs, Wilmington, DE (US); Weiying Gao, Landenberg, PA (US); Norman Herron, Newark, DE (US); Vsevolod Rostovtsev, Swarthmore, PA (US); Weishi Wu, Landenberg, PA (US); Yulong Shen, Plano, TX (US); Hong Meng, Wilmiington, DE (US)

(73) Assignee: E I DU PONT DE NEMOURS AND COMPANY, Wilmington, DE (US)

(21) Appl. No.: 13/989,493

(22) PCT Filed: Dec. 19, 2011
(86) PCT No.: PCT/US11/65789

§ 371 Date: May 24, 2013

Related U.S. Application Data
(60) Provisional application No. 61/424,089, filed on Dec. 17, 2010.

(51) Int. Cl. H01L 51/00

(52) U.S. Cl. CPC H01L 51/0058
USPC 257/40; 252/500; 585/27

(57) ABSTRACT

This invention relates to electroactive compositions including anthracene derivative compounds. It also relates to electronic devices in which at least one active layer includes such a composition.

### RELATED APPLICATION DATA

This application claims priority under 35 U.S.C. §119(e) from U.S. Provisional Application No. 61/424,089 filed on Dec. 17, 2010, which is incorporated by reference herein in its entirety.

### BACKGROUND

1. Field of the Disclosure

This invention relates to electroactive compositions including anthracene derivative compounds. It also relates to electronic devices in which at least one active layer includes such a composition.

2. Description of the Related Art

Organic electronic devices that emit light, such as light-emitting diodes that make up displays, are present in many different kinds of electronic equipment. In all such devices, an organic electroactive layer is sandwiched between two electrical contact layers. At least one of the electrical contact layers is light-transmitting so that light can pass through the electrical contact layer. The organic electroactive layer emits light through the light-transmitting electrical contact layer upon application of electricity across the electrical contact layers.

It is well known to use an electroactive layer comprising an organic electroluminescent compound as a dopant in a host material. Simple organic molecules such as anthracene, thiadiazole derivatives, and coumarin derivatives are known to show electroluminescence. Semiconductive conjugated polymers have also been used as electroluminescent components, as has been disclosed in, for example, U.S. Pat. No. 5,247,190, U.S. Pat. No. 5,408,109, and Published European Patent Application 443 861.

There is a continuing need for new materials for the electroactive layer of electronic devices.

### SUMMARY

There is provided an electroactive composition comprising an anthracene derivative host and an electroluminescent material, wherein the anthracene derivative host has Formula I(a):

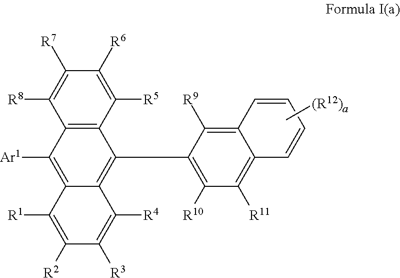

where:
Ar¹ is an aryl group;
R¹ through R⁸ and R¹¹ are the same or different and are selected from the group consisting of H, D, alkyl, silyl, and aryl;
R⁹ and R¹⁰ are the same or different and are selected from the group consisting of H, D, and C₁₋₅ alkyl, with the proviso that at least one of R⁹ and R¹⁰ is alkyl or silyl or silyl;
R¹² is the same or different at each occurrence and is selected from the group consisting of D, alkyl, silyl, and aryl; and
a is an integer from 0 to 4;

### or Formula I(b):

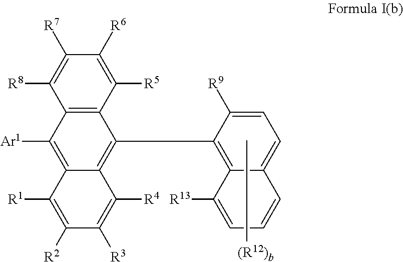

where:
Ar¹ is an aryl group;
R¹ through R⁸ and R¹¹ are the same or different and are selected from the group consisting of H, D, alkyl, alkoxy, aryl, aryloxy, silyl, and siloxane;
R⁹ and R¹³ are the same or different and are selected from the group consisting of H, D, and C₁₋₅ alkyl, with the proviso that at least one of R⁹ and R¹³ is alky or silyl;
R¹² is the same or different at each occurrence and is selected from the group consisting of D, alkyl, silyl, and aryl; and
b is an integer from 0 to 5.

### BRIEF DESCRIPTION OF THE DRAWINGS

Embodiments are illustrated in the accompanying figures to improve understanding of concepts as presented herein.

FIG. 1 includes an illustration of one example of an organic electronic device.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments are disclosed herein and are exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Electroactive Composition, the Electronic Device, and finally Examples.

### 1. DEFINITIONS AND CLARIFICATION OF TERMS

Before addressing details of embodiments described below, some terms are defined or clarified.

As used herein, the term “aliphatic ring” is intended to mean a cyclic is group that does not have delocalized pi electrons. In some embodiments, the aliphatic ring has no unsaturation. In some embodiments, the ring has one double or triple bond.

The term “alkoxy” refers to the group RO—, where R is an alkyl.

The term “alkyl” is intended to mean a group derived from an aliphatic hydrocarbon having one point of attachment, and includes a linear, a branched, or a cyclic group. The term is intended to include heteroalkyls. The term “hydrocarbon alkyl” refers to an alkyl group having no heteroatoms. The term “deuterated alkyl” is a hydrocarbon alkyl having at least one available H replaced by D. In some embodiments, an alkyl group has from 1-20 carbon atoms. The term “branched alkyl” refers to an alkyl group having at least one secondary or tertiary carbon. The term “secondary alkyl” refers to a branched alkyl group having a secondary carbon atom. The term “tertiary alkyl” refers to a branched alkyl group having a tertiary carbon atom. In some embodiments, the branched alkyl group is attached via a secondary or tertiary carbon.

The term “aryl” is intended to mean a group derived from an aromatic hydrocarbon having one point of attachment. The term “aromatic compound” is intended to mean an organic compound comprising at least one unsaturated cyclic group having delocalized pi electrons. The term is intended include heteroaryls. The term “hydrocarbon aryl” is intended to mean aromatic compounds having no heteroatoms in the ring. The term aryl includes groups which have a single ring and those which have multiple rings which can be joined by a single bond or fused together. The term “deuterated aryl” refers to an aryl group having at least one available H bonded directly to the aryl replaced by D. The term “arylene” is intended to mean a group derived from an aromatic hydrocarbon having two points of attachment. In some embodiments, an aryl group has from 3-60 carbon atoms.

The term “aryloxy” refers to the group RO—, where R is an aryl.

The term “blue light-emitting material” or “blue dopant” is intended to mean a material capable of emitting radiation that has an emission maximum at a wavelength in a range of approximately 400-480 nm. Similarly, “blue emission color” refers to color having a maximum at a wavelength in a range of approximately 400-480 nm.

The term “compound” is intended to mean an electrically uncharged substance made up of molecules that further consist of atoms, wherein the atoms cannot be separated by physical means. The phrase “adjacent to,” when used to refer to layers in a device, does not necessarily mean that one layer is immediately next to another layer. On the other hand, the phrase “adjacent R groups,” is used to refer to R groups that are next to each other in a chemical formula (i.e., R groups that are on atoms joined by a bond).

The term “deuterated” is intended to mean that at least one H has been replaced by D. The deuterium is present in at least 100 times the natural abundance level. A “deuterated analog” of compound X has the same structure as compound X, but with at least one D replacing an H.

The term “dopant” is intended to mean a material, within a layer including a host material, that changes the electronic characteristic(s) or the targeted wavelength(s) of radiation emission, reception, or filtering of the layer compared to the electronic characteristic(s) or the wavelength(s) of radiation emission, reception, or filtering of the layer in the absence of such material.

The term “electroactive” when referring to a layer or material, is intended to mean a layer or material that exhibits electronic or electro-radiative properties. In an electronic device, an electroactive material electronically facilitates the operation of the device. Examples of electroactive materials include, but are not limited to, materials which conduct, inject, transport, or block a charge, where the charge can be either an electron or a hole, and materials which emit radiation or exhibit a change in concentration of electron-hole pairs when receiving radiation. Examples of inactive materials include, but are not limited to, planarization materials, insulating materials, and environmental barrier materials.

The term “electroluminescence” refers to the emission of light from a material in response to an electric current passed through it. “Electroluminescent” refers to a material that is capable of electroluminescence.

The term “emission maximum” is intended to mean the highest intensity of radiation emitted. The emission maximum has a corresponding wavelength.

The term “green light-emitting material” or “green dopant” is intended to mean a material capable of emitting radiation that has an emission maximum at a wavelength in a range of approximately 480-600 nm. Similarly, “green emission color” refers to color having a maximum at a wavelength in a range of approximately 480-560 nm.

The prefix “hetero” indicates that one or more carbon atoms have been replaced with a different atom. In some embodiments, the different atom is N, O, or S.

The term “host material” is intended to mean a material to which a dopant is added. The host material may or may not have electronic characteristic(s) or the ability to emit, receive, or filter radiation. In some embodiments, the host material is present in higher concentration.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing.

The term “organic electronic device” or sometimes just “electronic device” is intended to mean a device including one or more organic semiconductor layers or materials.

The term “silyl” refers to the group R₃Si—, where R is H, D, C1-20 alkyl, fluoroalkyl, or aryl. In some embodiments, one or more carbons in an R alkyl group are replaced with Si. In some embodiments, the silyl groups are (hexyl)₂Si(CH₃)CH₂CH₂Si(CH₃)₂— and [CF₃(CF₂)₅CH₂CH₂]₂Si(CH₃)—.

All groups can be substituted or unsubstituted unless otherwise indicated. In some embodiments, the substituents are selected from the group consisting of D, halide, alkyl, alkoxy, silyl, aryl, aryloxy, cyano, and NR₂, where R is alkyl or aryl.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

The IUPAC numbering system is used throughout, where the groups from the Periodic Table are numbered from left to right as 1-18 (CRC Handbook of Chemistry and Physics, 81^{st} Edition, 2000).

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the disclosed subject matter hereof, is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Further, unless expressly stated to the contrary, “or” refers to an is inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

### 2 ELECTROACTIVE COMPOSITION

The electroactive composition described herein comprises an anthracene derivative host having Formula I(a) or Formula I(b) and an electroluminescent dopant material. In some embodiments, the dopant has an emission color that is blue or green.

In some embodiments, the electroactive composition consists essentially of a host material having Formula I(a) or Formula I(b) and one or more electroluminescent dopants. In some embodiments, the electroactive layer consists essentially of a first host material having Formula I(a) or Formula I(b), a second host material, and an electroluminescent dopant. Examples of second host materials include, but are not limited to, chrysenes, phenanthrenes, triphenylenes, phenanthrolines, naphthalenes, anthracenes, quinolines, isoquinolines, quinoxalines, phenylpyridines, benzodifurans, and metal quinolinate complexes.

The amount of dopant present in the electroactive composition is generally in the range of 3-20% by weight, based on the total weight of the composition; in some embodiments, 5-15% by weight. When a second host is present, the ratio of first host having Formula I(a) or Formula I(b) to to second host is generally in the range of 1:20 to 20:1; in some embodiments, 5:15 to 15:5. In some embodiments, the first host material having Formula I(a) or Formula I(b) is at least 50% by weight of the total host material; in some embodiments, at least 70% by weight.

a. Anthracene Derivative Host

The anthracene derivative host material has Formula I(a):

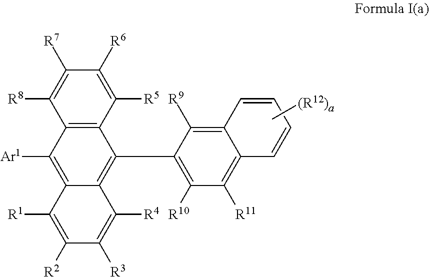

where:
Ar¹ is an aryl group;
R¹ through R⁸ and R¹¹ are the same or different and are selected from the group consisting of H, D, alkyl, silyl, and aryl;
R⁹ and R¹⁰ are the same or different and are selected from the group consisting of H, D, and C₁₋₅ alkyl, with the proviso that at least one of R⁹ and R¹⁰ is alkyl or silyl;
R¹² is the same or different at each occurrence and is selected from the group consisting of D, alkyl, silyl, and aryl; and
a is an integer from 0 to 4;

### or Formula I(b):

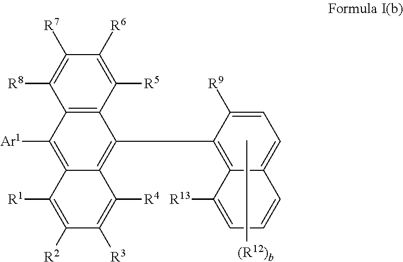

where:
Ar¹ is an aryl group;
R¹ through R⁸ and R¹¹ are the same or different and are selected from the group consisting of H, D, alkyl, alkoxy, aryl, aryloxy, silyl, and siloxane;
R⁹ and R¹³ are the same or different and are selected from the group consisting of H, D, and C₁₋₅ alkyl, with the proviso that at least one of R⁹ and R¹³ is alkyl or silyl;
R¹² is the same or different at each occurrence and is selected from the group consisting of D, alkyl, silyl, and aryl; and
b is an integer from 0 to 5.

In some embodiments of Formulae I(a) and I(b), Ar¹ is selected from the group consisting of phenyl, naphthyl, phenanthryl, anthracenyl, phenylnaphthylene, naphthylphenylene, deuterated analogs thereof, and a group having Formula II:

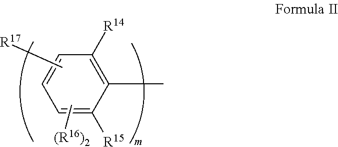

where:
R¹⁴ and R¹⁵ are the same or different and are selected from the group consisting of H, D, and C₁₋₅ alkyl;
R¹⁶ is the same or different at each occurrence and is selected from the group consisting of H, D, alkyl, alkoxy, siloxane and silyl, or adjacent R¹⁶ groups may be joined together to form an aromatic ring;
R¹⁷ is selected from the group consisting of H, D, alkyl, silyl, and aryl; and
m is the same or different at each occurrence and is an integer from 1 to 6.

In some embodiments of Formulae I(a) and I(b), Ar¹ is selected from the group consisting of phenyl, naphthyl, phenylnaphthylene, naphthylphenylene, deuterated analogs thereof, and a group having Formula III:

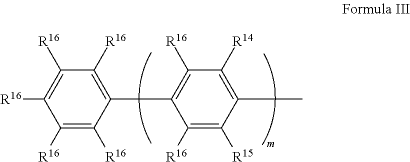

where R¹⁴ through R¹⁶ and m are as defined above for Formula II. In some embodiments, m is an integer from 1 to 3.

In some embodiments of Formulae II and III, at least one of R¹⁴ and R¹⁵ is a C₁₋₅ alkyl. In some embodiments, one or both of R¹⁴ and R¹⁵ is a methyl group.

In some embodiments of Formulae I(a) and I(b), Ar¹ is a heteroaryl group. In some embodiments, the heteroaryl group is selected from the group consisting of furan, benzofuran, dibenzofuran, pyran, benzopyran, and dibenzopyran.

In some embodiments of Formulae I(a) and I(b), R¹ through R⁸ are selected from H and D.

In some embodiments of Formulae I(a) and I(b), at least one of R¹ through R⁸ is selected from alkyl, alkoxy, aryl, aryloxy, siloxane, and silyl, and the remainder of R¹ through R⁸ are selected from H and D. In some embodiments, R² is selected from alkyl, alkoxy, aryl, aryloxy, siloxane, and silyl. In some embodiments, R² is selected from alkyl and aryl.

In some embodiments of Formulae I(a) and I(b), at least one R¹² is an aryl group. In some embodiments, at least one R¹² is selected from the group consisting of phenyl, naphthyl, phenanthryl, anthracenyl, and deuterated analogs thereof.

In some embodiments of Formula I(a), both R⁹ and R¹⁰ are alkyl groups. In some embodiments, both R⁹ and R¹⁰ are methyl groups.

In some embodiments of Formula I(a), a=1 and R¹² is selected from the group consisting of methyl, phenyl and naphthyl.

In some embodiments of Formula I(b), both R⁹ and R¹³ are alkyl groups. In some embodiments, both R⁹ and R¹³ are methyl groups.

In some embodiments of Formula I(b), b=1 and R¹² is selected from the group consisting of methyl, phenyl and naphthyl.

In some embodiments, the anthracene derivative compound described herein is at least 50% deuterated. By this is meant that at least 50% of the H are replaced by D. In some embodiments, the compound is at least 60% deuterated; in some embodiments, at least 70% deuterated; in some embodiments, at least 80% deuterated; in some embodiments, at least 90% deuterated. In some embodiments, the compound is 100% deuterated.

In some embodiments of Formula I(a), there can be any combination of the following: (i) Ar¹ is selected from the group consisting of phenyl, naphthyl, phenanthryl, anthracenyl, phenylnaphthylene, naphthylphenylene, deuterated analogs thereof, a group having Formula II, and a group having Formula III, or Ar¹ is a heteroaryl group selected from the group consisting of furan, benzofuran, dibenzofuran, pyran, benzopyran, and dibenzopyran; (ii) R¹ through R⁸ are selected from H and D, or at least one of R¹ through R⁸ is selected from alkyl, alkoxy, aryl, aryloxy, siloxane, and silyl, and the remainder of R¹ through R⁸ are selected from H and D; (iii) R² is selected from alkyl, alkoxy, aryl, aryloxy, siloxane, and silyl; (iv) at least one R¹² is an aryl group; (v) both R⁹ and R¹⁰ are alkyl groups; (vi) a=1 and R¹² is selected from the group consisting of methyl, phenyl and naphthyl.

In some embodiments of Formula I(b), there can be any combination of the following: (i) Ar¹ is selected from the group consisting of phenyl; naphthyl, phenanthryl, anthracenyl, phenylnaphthylene, naphthylphenylene, deuterated analogs thereof, a group having Formula II, and a group having Formula III, or Ar¹ is a heteroaryl group selected is from the group consisting of furan, benzofuran, dibenzofuran, pyran, benzopyran, and dibenzopyran; (ii) R¹ through R⁸ are selected from H and D, or at least one of R¹ through R⁸ is selected from alkyl, alkoxy, aryl, aryloxy, siloxane, and silyl, and the remainder of R¹ through R⁸ are selected from H and D; (iii) R² is selected from alkyl; alkoxy, aryl, aryloxy, siloxane, and silyl; (iv) at least one R¹² is an aryl group; (v) both R⁹ and R¹³ are alkyl groups; (vi) b=1 and R¹² is selected from the group consisting of methyl, phenyl and naphthyl.

Some non-limiting examples of compounds having Formula I(a) or Formula I(b) are shown below:

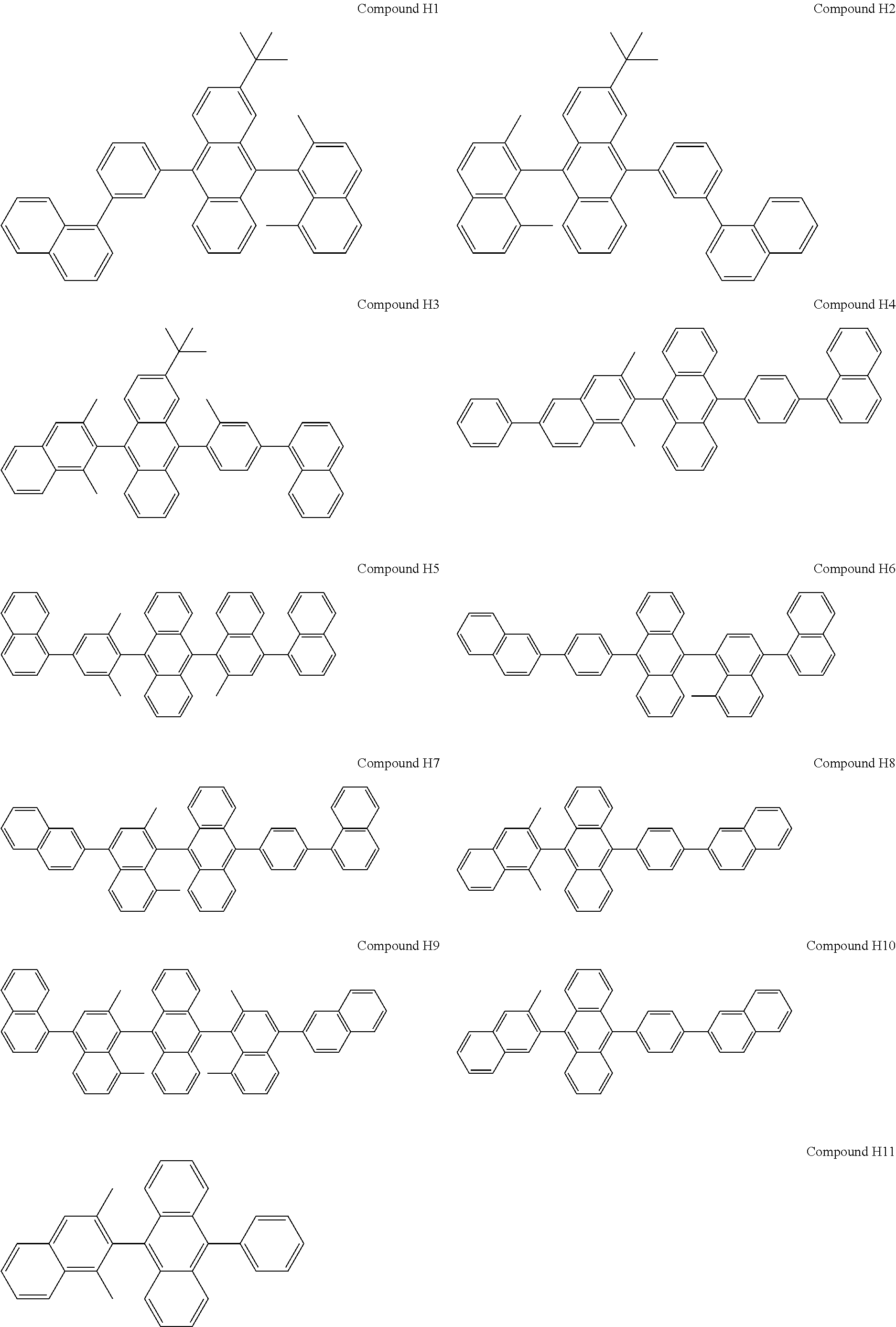

The anthracene derivative compounds can be prepared by known coupling and substitution reactions. Such reactions are well-known and have been described extensively in the literature. Exemplary references include: Yamamoto, Progress in Polymer Science, Vol. 17, p 1153 (1992); Colon et al., Journal of Polymer Science, Part A, Polymer chemistry Edition, Vol. 28, p. 367 (1990); U.S. Pat. No. 5,962,631, and published PCT application WO 00/53565; T. Ishiyama et al., J. Org. Chem. 1995 60, 7508-7510; M. Murata et al., J. Org. Chem. 1997 62, 6458-6459; M. Murata et al., J. Org. Chem. 2000 65, 164-168; L. Zhu, et al., J. Org. Chem. 2003 68, 3729-3732; Stille, J. K. Angew. Chem. Int. Ed. Engl. 1986, 25, 508; Kumada, M. Pure. Appl. Chem. 1980, 52, 669; Negishi, E. Acc. Chem. Res. 1982, 15, 340; Hartwig, J., Synlett 2006, No. 9, pp. 1283-1294; Hartwig, J., Nature 455, No. 18, pp. 314-322;

The deuterated analog compounds can be prepared in a similar manner using deuterated precursor materials or, more generally, by treating the non-deuterated compound with deuterated solvent, such as d6-benzene, in the presence of a Lewis acid H/D exchange catalyst, such as aluminum trichloride or ethyl aluminum chloride, or acids such as CF₃COOD, DCl, etc. Deuteration reactions have also been described in copending application [UC0917].

The compounds described herein can be formed into films using liquid deposition techniques. This is further illustrated in the examples. Alternatively, they can be formed into films using vapor deposition techniques.

b. Electroluminescent Material

The dopant is an electroluminescent material which is capable of electroluminescence having an emission maximum between 380 and 750 nm. In some embodiments, the dopant has an emission color that is red, green, or blue. In some embodiments, the dopant has an emission color that is green or blue.

Electroluminescent (“EL”) materials which can be used as a dopant in the electroactive layer, include, but are not limited to, small molecule organic fluorescent compounds, fluorescent and phosphorescent metal complexes, conjugated polymers, and mixtures thereof. Examples of fluorescent compounds include, but are not limited to, chrysenes, pyrenes, perylenes, rubrenes, coumarins, anthracenes, thiadiazoles, derivatives thereof, and mixtures thereof. Examples of metal complexes include, but are not limited to, metal chelated oxinoid compounds. Examples of conjugated polymers include, but are not limited to poly(phenylenevinylenes), polyfluorenes, poly(spirobifluorenes), polythiophenes, poly(p-phenylenes), copolymers thereof, and mixtures thereof.

Examples of red light-emitting materials include, but are not limited to, periflanthenes, fluoranthenes, and perylenes. Red light-emitting materials have been disclosed in, for example, U.S. Pat. No. 6,875,524, and published US application 2005-0158577.

Examples of green light-emitting materials include, but are not limited to, diaminoanthracenes, and polyphenylenevinylene polymers. Green light-emitting materials have been disclosed in, for example, published POT application WO 2007/021117.

Examples of blue light-emitting materials include, but are not limited to, diarylanthracenes, diaminochrysenes, diaminopyrenes, and polyfluorene polymers. Blue light-emitting materials have been disclosed to in, for example, U.S. Pat. No. 6,875,524, and published US applications 2007-0292713 and 2007-0063638.

In some embodiments, the dopant is an organic compound. In some embodiments, the dopant is selected from the group consisting of a non-polymeric spirobifluorene compound and a fluoranthene compound.

In some embodiments, the dopant is a compound having aryl amine groups. In some embodiments, the electroactive dopant is selected from the formulae below:

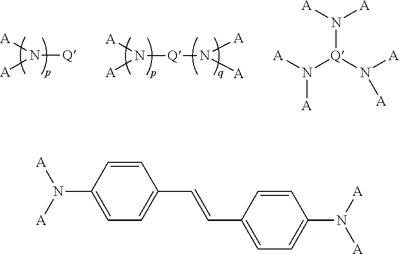

where:

A is the same or different at each occurrence and is an aromatic group having from 3-60 carbon atoms;

Q′ is a single bond or an aromatic group having from 3-60 carbon atoms;

p and q are independently an integer from 1-6.

In some embodiments of the above formula, at least one of A and Q′ in each formula has at least three condensed rings. In some to embodiments, p and q are equal to 1.

In some embodiments, Q′ is a styryl or styrylphenyl group.

In some embodiments, Q is an aromatic group having at least two condensed rings. In some embodiments, Q′ is selected from the group consisting of naphthalene, anthracene, chrysene, pyrene, tetracene, is xanthene, perylene, coumarin, rhodamine, quinacridone, and rubrene.

In some embodiments, A is selected from the group consisting of phenyl, biphenyl, tolyl, naphthyl, naphthylphenyl, and anthracenyl groups.

In some embodiments, the dopant has the formula below:

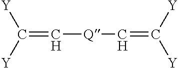

where:

Y is the same or different at each occurrence and is an aromatic group having 3-60 carbon atoms;

Q″ is an aromatic group, a divalent triphenylamine residue group, or a single bond.

In some embodiments, the dopant is an aryl acene. In some embodiments, the dopant is a non-symmetrical aryl acene.

In some embodiments, the dopant is an anthracene derivative having Formula IV;

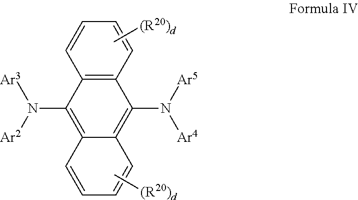

wherein:
R²⁰ is the same or different at each occurrence and is selected from the group consisting of D, alkyl, alkoxy and aryl, where adjacent R¹⁰ groups may be joined together to form a 5- or 6-membered aliphatic ring;
Ar² through Ar⁵ are the same or different and are selected from the group consisting of aryl groups and deuterated aryl groups;
d is the same or different at each occurrence and is an integer from 0 to 4; and

In some embodiments, the dopant is a chrysene derivative having Formula V:

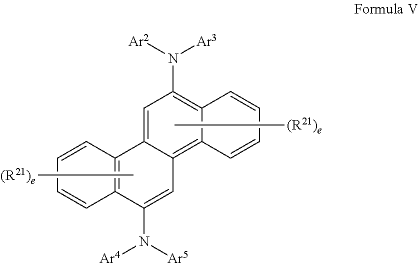

wherein:
R²¹ is the same or different at each occurrence and is selected from the group consisting of D, alkyl, alkoxy aryl, fluoro, cyano, nitro, —SO₂R, where R is alkyl or perfluoroalkyl, where adjacent R²¹ groups may be joined together to form a 5- or 6-membered aliphatic ring;
Ar² through Ar⁵ are the same or different and are selected from the group consisting of aryl groups; and
e is the same or different at each occurrence and is an integer from 0 to 5

Some non-limiting examples of green dopants are compounds D1 through D7 shown below.

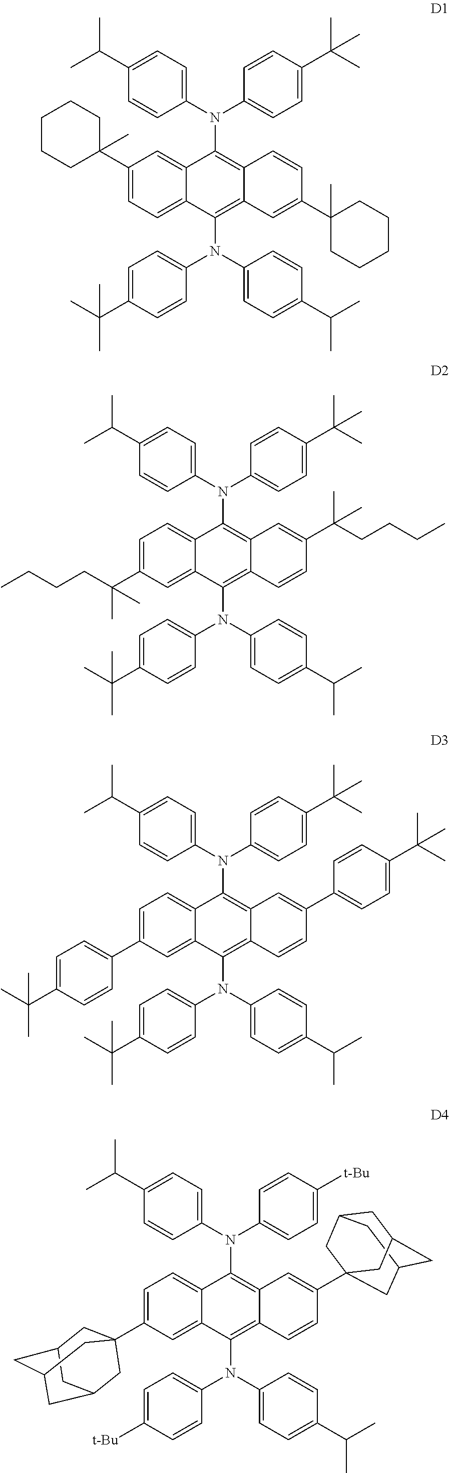

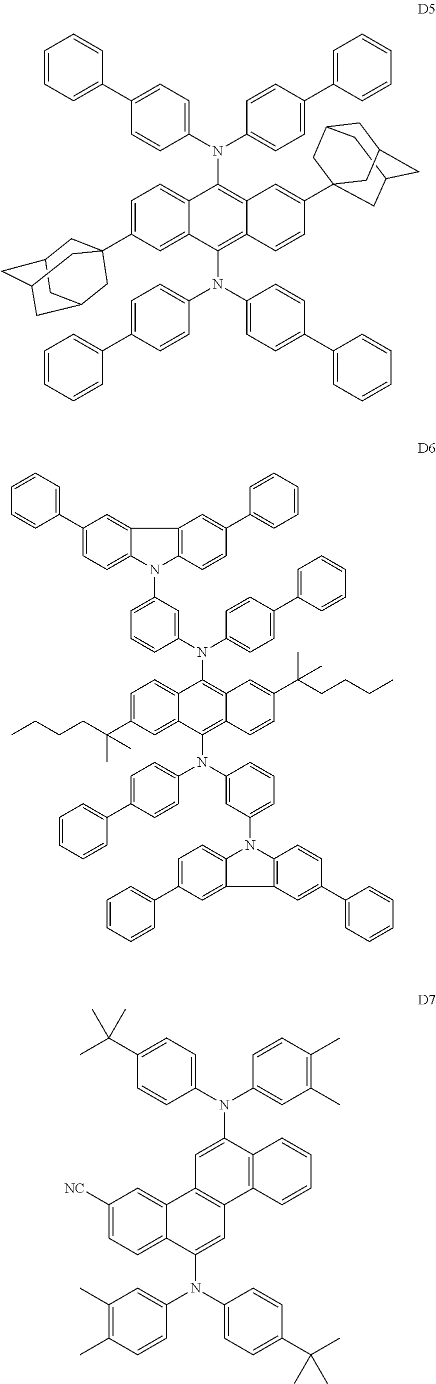 [SMILES: c1ccc(-c2ccc(N(c3ccc(-c4ccccc4)cc3)c3c4ccc(C56CC7CC(CC(C7)C5)C6)cc4c(N(c4ccc(-c5ccccc5)cc4)c4ccc(-c5ccccc5)cc4)c4ccc(C56CC7CC(CC(C7)C5)C6)cc34)cc2)cc1 ; CCCCC(C)(C)c1ccc2c(N(c3ccc(-c4ccccc4)cc3)c3cccc(-n4c5ccc(-c6ccccc6)cc5c5cc(-c6ccccc6)ccc54)c3)c3cc(C(C)(C)CCCC)ccc3c(N(c3ccc(-c4ccccc4)cc3)c3cccc(-n4c5ccc(-c6ccccc6)cc5c5cc(-c6ccccc6)ccc54)c3)c2c1 ; Cc1ccc(N(c2ccc(C(C)(C)C)cc2)c2cc3c4cc(C#N)ccc4c(N(c4ccc(C(C)(C)C)cc4)c4ccc(C)c(C)c4)cc3c3ccccc23)cc1C]

Some non-limiting examples of blue dopants are compounds D8 through D14 shown below.

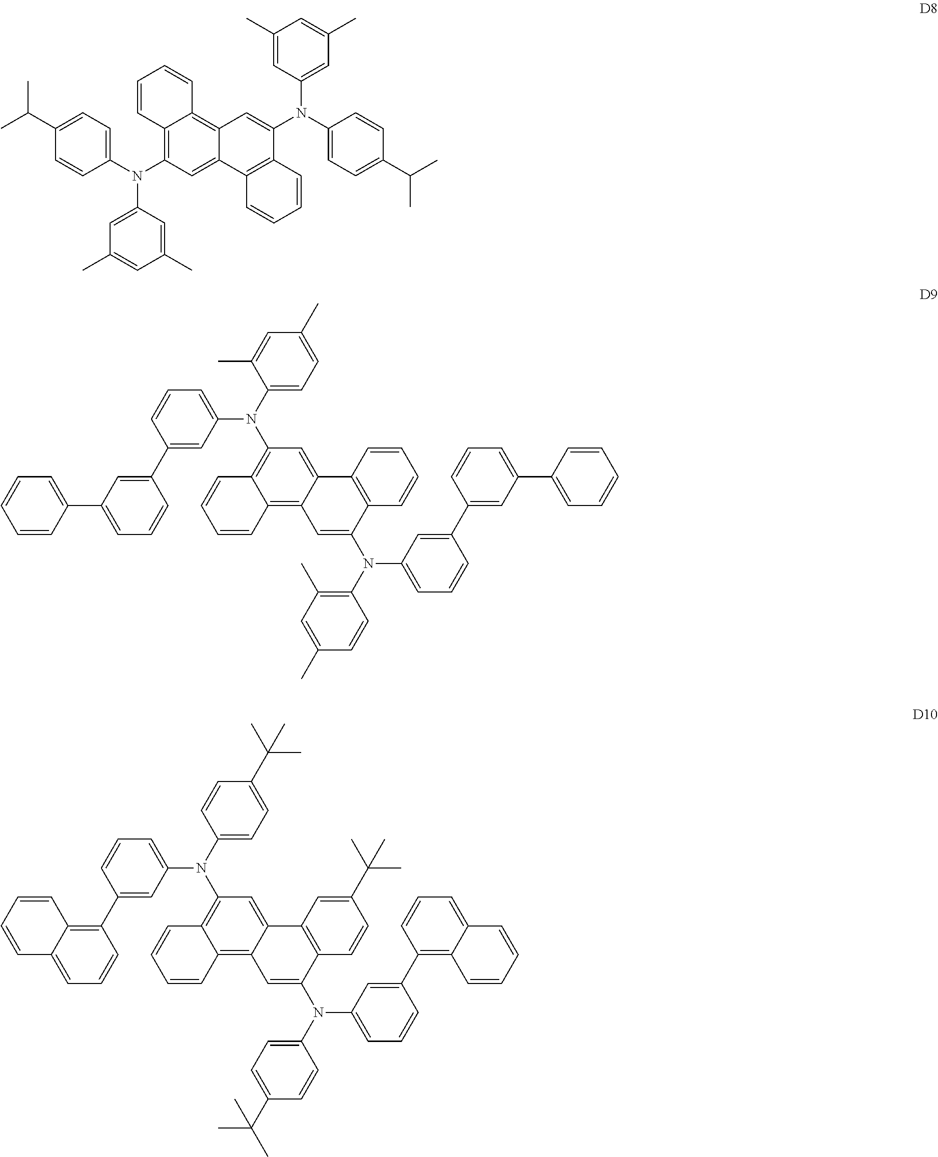 [SMILES: Cc1cc(C)cc(N(c2ccc(C(C)C)cc2)c2cc3c4ccccc4c(N(c4ccc(C(C)C)cc4)c4cc(C)cc(C)c4)cc3c3ccccc23)c1 ; Cc1ccc(N(c2cccc(-c3cccc(-c4ccccc4)c3)c2)c2cc3c4ccccc4c(N(c4cccc(-c5cccc(-c6ccccc6)c5)c4)c4ccc(C)cc4C)cc3c3ccccc23)c(C)c1 ; CC(C)(C)c1ccc(N(c2cccc(-c3cccc4ccccc34)c2)c2cc3c4cc(C(C)(C)C)ccc4c(N(c4ccc(C(C)(C)C)cc4)c4cccc(-c5cccc6ccccc56)c4)cc3c3ccccc23)cc1]

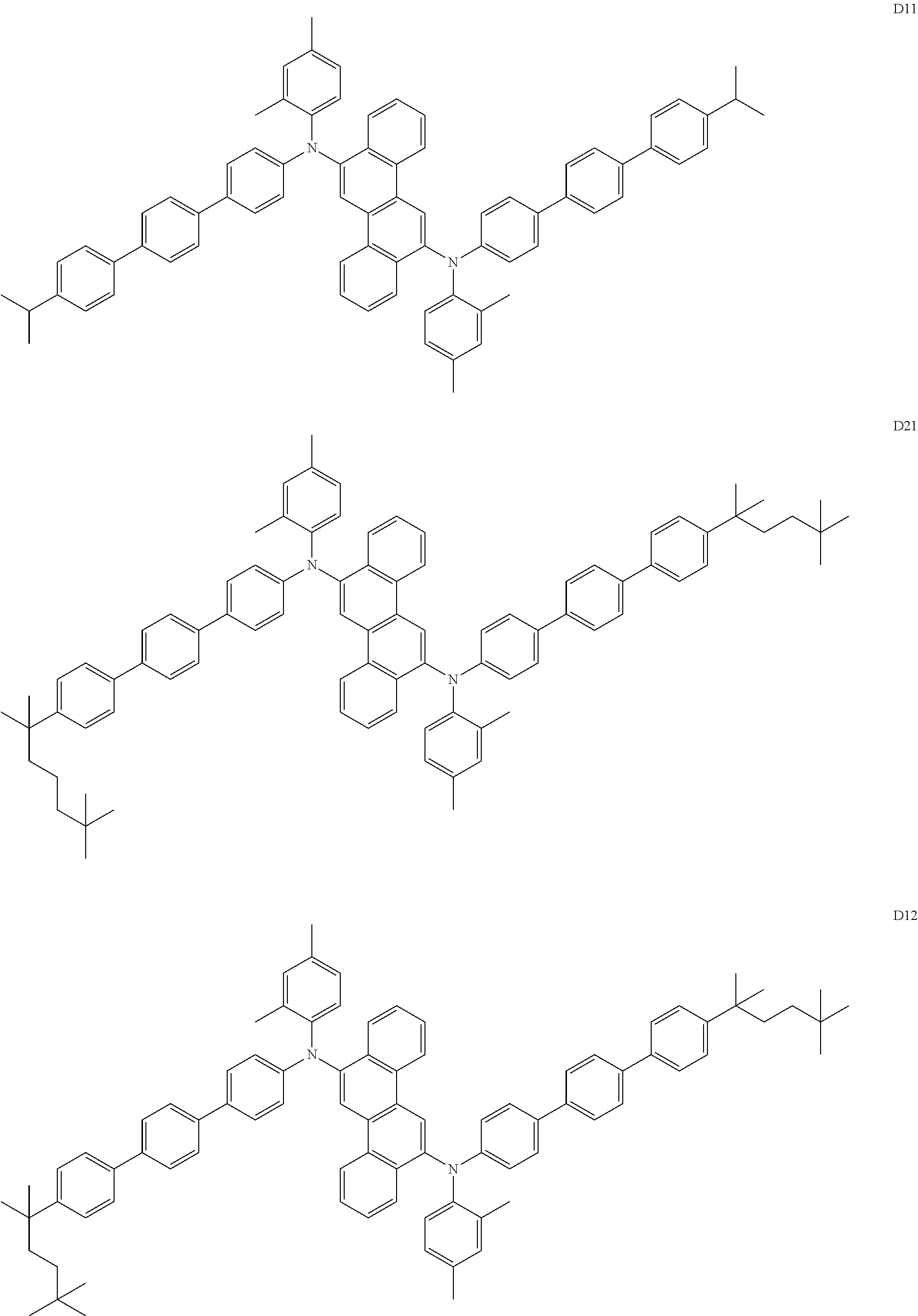

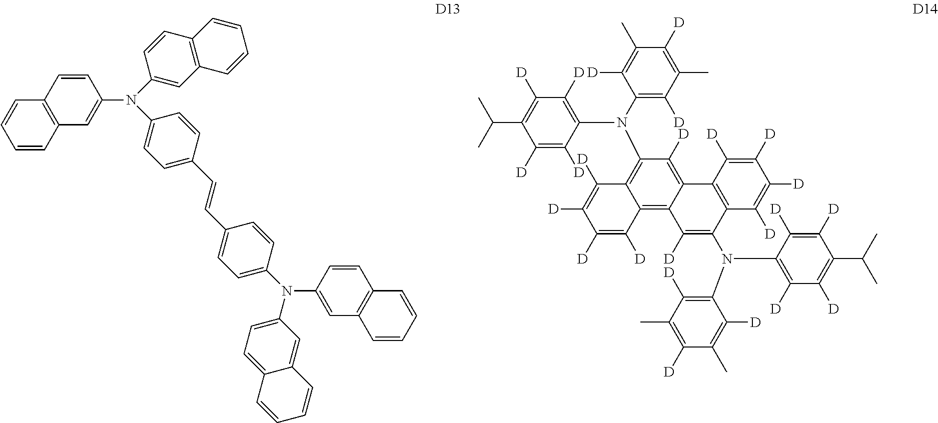 [SMILES: C(=C\c1ccc(N(c2ccc3ccccc3c2)c2ccc3ccccc3c2)cc1)/c1ccc(N(c2ccc3ccccc3c2)c2ccc3ccccc3c2)cc1 ; [2H]c1c(C)c([2H])c(N(c2c([2H])c([2H])c(C(C)C)c([2H])c2[2H])c2c([2H])c3c4c([2H])c([2H])c([2H])c([2H])c4c(N(c4c([2H])c([2H])c(C(C)C)c([2H])c4[2H])c4c([2H])c(C)c([2H])c(C)c4[2H])c([2H])c3c3c([2H])c([2H])c([2H])c([2H])c23)c([2H])c1C]

In some embodiments, the electroluminescent dopant is selected from the group consisting of amino-substituted chrysenes and amino-Substituted anthracenes.

The compositions described herein can be formed into films using liquid deposition techniques.

### 3. ELECTRONIC DEVICE

Organic electronic devices that may benefit from having one or more layers comprising the compounds described herein include, but are not limited to, (1) devices that convert electrical energy into radiation (e.g., a light-emitting diode, light-emitting diode display, light-emitting luminaire, or diode laser), (2) devices that detect signals through electronics is processes (e.g., photodetectors, photoconductive cells, photoresistors, photoswitches, phototransistors, phototubes, IR detectors), (3) devices that convert radiation into electrical energy, (e.g., a photovoltaic device or solar cell), and (4) devices that include one or more electronic components that include one or more organic semi-conductor layers (e.g., a thin film transistor or diode). The compounds of the invention often can be useful in applications such as oxygen sensitive indicators and as luminescent indicators in bioassays.

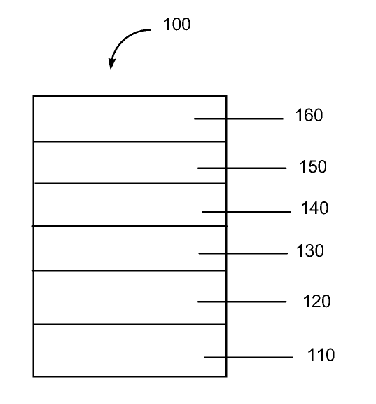

One illustration of an organic electronic device structure is shown in FIG. 1. The device 100 has a first electrical contact layer, an anode layer 110 and a second electrical contact layer, a cathode layer 160, and an electroactive layer 140 between them. Adjacent to the anode may be a hole injection layer 120. Adjacent to the hole injection layer may be a hole transport layer 130, comprising hole transport material, Adjacent to the cathode may be an electron transport layer 150, comprising an electron transport material Devices may use one or more additional hole injection or hole transport layers (not shown) next to the anode 110 and/or one or more additional electron injection or electron transport layers (not shown) next to the cathode 160.

Layers 120 through 150 are individually and collectively referred to as the active layers.

In one embodiment, the different layers have the following range of thicknesses: anode 110, 500-5000 Å, in one embodiment 1000-2000 Å; hole injection layer 120, 50-2000 Å, in one embodiment 200-1000 Å; hole is transport layer 130, 50-2000 Å, in one embodiment 200-1000 Å; electroactive layer 140, 10-2000 Å, in one embodiment 100-1000 Å; layer 150, 50-2000 Å, in one embodiment 100-1000 Å; cathode 160, 200-10000 Å, in one embodiment 300-5000 Å. The location of the electron-hole recombination zone in the device, and thus the emission spectrum of the device, can be affected by the relative thickness of each layer. The desired ratio of layer thicknesses will depend on the exact nature of the materials used.

Depending upon the application of the device 100, the electroactive layer 140 can be a light-emitting layer that is activated by an applied voltage (such as in a light-emitting diode or light-emitting electrochemical cell), or a layer of material that responds to radiant energy and generates a signal with or without an applied bias voltage (such as in a photodetector). Examples of photodetectors include photoconductive cells, photoresistors, photoswitches, phototransistors, and phototubes, and photovoltaic cells, as these terms are described in Markus, John, Electronics and Nucleonics Dictionary, 470 and 476 (McGraw-Hill, Inc. 1966).

The new electroactive composition described herein is useful as layer 140.

In some embodiments, the devices have additional layers to aid in processing or to improve functionality.

a. Electroactive Layer

The image quality from color displays is measured in part by color gamut—the number of colors which can be produced by combining the light from the three primary red, green, and blue (“RGB”) sub-pixels in varying relative intensities. The color gamut size is dictated by the emission wavelength energy and width of the primaries. Ideally, the RGB subpixels will have emission maxima of 700, 520, and 460 nm, respectively, with 1-2 nanometer widths. In reality the widths are often 10's of nanometers. In an organic light-emitting diode (“OLED”) display, the blue emitter is rarely, if ever, intrinsically narrow enough to meet the National Television Standard Committee (“NTSC”) standard of CIE (x,y)=(0.15, 0.06). As used herein, CIE (x,y) refers to the x and y color coordinates according to the C.I.E. chromaticity scale (Commission Internationale de L'Eclairage, 1931). The OLED blue color can be sharpened to meet this standard by filtering the light and/or by incorporating microcavity structures in the device, but both of these solutions add cost and the latter compromises viewing angle, another important image quality parameter. Another issue with state of the art deep blue OLEDs is relatively poor quantum efficiency, arising from the difficulty in confining/trapping charge on the very wide gap emitter.

The best performing blue OLEDs in terms of color, efficiency, and lifetime currently have quantum efficiencies that exceed 5% with several thousand hour lifetimes at high luminance. However, the intrinsic emission color is typically no better than CIE(x,y)˜(0.14, 0.12). The color can be improved to CIE(x,y)˜(0.14, 0.10) with dopants having a wider HOMO-LUMO bandgap. However, in this case the bandgap of the host and dopant become nearly identical. This leads to competitive host emission and quantum efficiencies <5%, while still not meeting the NTSC standard. Hence there is a need for deeper blue OLEDs to satisfy the NTSC standard and which also provide quantum efficiencies ≧5%.

In some embodiments, the anthracene compounds described herein have wide bandgaps. This is due to the disruption in conjugation caused by the alkyl or silyl group at R⁹, R¹⁰, or R¹³. The host compounds are suitable for dopants that have deep blue emission color in electroactive layer 140. The hosts can also be used for dopants with other colors of emission.

In some embodiments, the electroactive layer consists essentially of a host material having Formula I and one or more electroluminescent dopants. In some embodiments, the electroactive layer consists essentially of a first host material having Formula I, a second host material, and an electroluminescent dopant. Examples of second host materials include, but are not limited to, chrysenes, phenanthrenes, triphenylenes, phenanthrolines, naphthalenes, anthracenes, quinolines, isoquinolines, quinoxalines, phenylpyridines, benzodifurans, and metal quinolinate complexes.

The amount of dopant present in the electroactive composition is generally in the range of 3-20% by weight, based on the total weight of the composition; in some embodiments, 5-15% by weight. When a second host is present, the ratio of first host having Formula I to second host is generally in the range of 1:20 to 20:1; in some embodiments, 5:15 to 15:5. In some embodiments, the first host material having Formula I is at least 50% by weight of the total host material; in some embodiments, at least 70% by weight.

In some embodiments, the second host material has Formula VI:

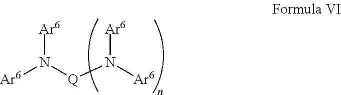

where:
Ar⁶ is the same or different at each occurrence and is an aryl group;
Q is selected from the group consisting of multivalent aryl groups and

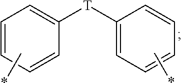

T is selected from the group consisting of (CR′)ₐ, SiR₂, S, SO₂, PR, PO, PO₂, BR, and R;
R is the same or different at each occurrence and is selected from the group consisting of alkyl, and aryl;
R′ is the same or different at each occurrence and is selected from the group consisting of H and alkyl;
a is an integer from 1-6; and
n is an integer from 0-6.
   While n can have a value from 0-6, it will be understood that for some Q groups the value of n is restricted by the chemistry of the group. In some embodiments, n is 0 or 1.

In some embodiments of Formula VI, adjacent Ar groups are joined together to form rings such as carbazole. In Formula VI, “adjacent” means that the Ar groups are bonded to the same N.

In some embodiments, Ar⁶ is independently selected from the group consisting of phenyl, biphenyl, terphenyl, quaterphenyl, naphthyl, phenanthryl, naphthylphenyl, and phenanthrylphenyl. Analogs higher than quaterphenyl, having 5-10 phenyl rings, can also be used.

In some embodiments, at least one of Ar⁶ has at least one substituent. Substituent groups can be present in order to alter the physical or electronic properties of the host material. In some embodiments, the substituents improve the processibility of the host material. In some embodiments, the substituents increase the solubility and/or increase the Tg of the host material. In some embodiments, the substituents are selected from the group consisting of D, alkyl groups, alkoxy groups, silyl groups, siloxane, and combinations thereof.

In some embodiments, Q is an aryl group having at least two fused rings. In some embodiments, Q has 3-5 fused aromatic rings. In some embodiments, Q is selected from the group consisting of chrysene, phenanthrene, triphenylene, phenanthroline, naphthalene, anthracene, quinoline and isoquinoline.

b. Other Device Layers

The other layers in the device can be made of any materials that are known to be useful in such layers.

The anode 110, is an electrode that is particularly efficient for injecting positive charge carriers. It can be made of, for example, materials containing a metal, mixed metal, alloy, metal oxide or mixed-metal oxide, or it can be a conducting polymer, or mixtures thereof. Suitable metals include the Group 11 metals, the metals in Groups 4-6, and the Group 8-10 transition metals. If the anode is to be light-transmitting, mixed-metal oxides of Groups 12, 13 and 14 metals, such as indium-tin-oxide, are generally used. The anode 110 can also comprise an organic material such as polyaniline as described in “Flexible light-emitting diodes made from soluble conducting polymer,” Nature vol. 357, pp 477-479 (11 Jun. 1992). At least one of the anode and cathode is desirably at least partially transparent to allow the generated light to be observed.

The hole injection layer 120 comprises hole injection material and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Hole injection materials may be polymers, oligomers, or small molecules. They may be vapour deposited or deposited from liquids which may be in the form of solutions, dispersions, suspensions, emulsions, colloidal mixtures, or other compositions.

The hole injection layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid); and the like.

The hole injection layer can comprise charge transfer compounds, and the like, such as copper phthalocyanine and the tetrathiafulvalene-tetracyanoquinodimethane system (TTF-TCNQ).

In some embodiments, the hole injection layer comprises at least one electrically conductive polymer and at least one fluorinated acid polymer. Such materials have been described in, for example, published U.S. patent applications 2004-0102577, 2004-0127637, and 2005/205860

In some embodiments, the hole transport layer 130 comprises the new deuterated compound of Formula I. Examples of other hole transport is materials for layer 130 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules are: N,N′-diphenyl-N,N′-bis(3-methylphenyl)-[1,1′-biphenyl]-4,4′-diamine (TPD), 1,1-bis[(di-4-tolylamino)phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (FDA), a-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3-[p-(diethylamino)styryl]-5-[p-(diethylamino)phenyl]pyrazoline (PPR OF DEASP), 1,2-trans-bis(9H-carbazol-9-yl)cyclobutane (DCZB), N,N,′,N′-tetrakis(4-methylphenyl)-(1,1′-biphenyl)-4,4′-diamine (TTB), N,N′-bis(naphthalen-1-yl)-N,N′-bis-(phenyl)benzidine (□-NPB), and porphyrinic compounds, such as copper phthalocyanine. Commonly used hole transporting polymers are polyvinylcarbazole, (phenylmethyl)-polysilane, and polyaniline. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable. Examples of crosslinkable hole transport polymers can be found in, for example, published US patent application 2005-0184287 and published PCT application WO 2005/052027. In some embodiments, the hole transport layer is doped with a p-dopant, such as tetrafluorotetracyanoquinodimethane and perylene-3,4,9,10-tetracarboxylic-3,4,9,10-dianhydride.

In some embodiments, the electron transport layer 150 comprises the new deuterated compound of Formula I. Examples of other electron transport materials which can be used in layer 150 include metal chelated oxinoid compounds, such as tris(8-hydroxyquinolato)aluminum (Alq₃); bis(2-methyl-8-quinolinolato)(para-phenyl-phenolato)aluminum(III) (BAlQ); and azole compounds such as 2-(4-biphenylyl)-5-(4-t-butylphenyl)-1,3,4-s oxadiazole (PBD) and 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthroline derivatives such as 9,10-diphenylphenanthroline (DPA) and 2,9-dimethyl-4,7-diphenyl-1,10-phenanthroline (DDPA); and mixtures thereof. The electron-transport layer may also be doped with n-dopants, such as Cs or other alkali metals. Layer 150 can function both to facilitate electron transport, and also serve as a buffer layer or confinement layer to prevent quenching of the exciton at layer interfaces. Preferably, this layer promotes electron mobility and reduces exciton quenching.

The cathode 160, is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used. Li- or Cs-containing organometallic compounds, LiF, CsF, and Li₂O can also be deposited between the organic layer and the cathode layer to lower the operating voltage.

It is known to have other layers in organic electronic devices. For example, there can be a layer (not shown) between the anode 110 and hole injection layer 120 to control the amount of positive charge injected and/or to provide band-gap matching of the layers, or to function as a protective layer. Layers that are known in the art can be used, such as copper phthalocyanine, silicon oxy-nitride, fluorocarbons, silanes, or an ultra-thin layer of a metal, such as Pt. Alternatively, some or all of anode layer 110, active layers 120, 130, 140, and 150, or cathode layer 160, can be surface-treated to increase charge carrier transport efficiency. The choice of materials for each of the component layers is preferably determined by balancing the positive and negative charges in the emitter layer to provide a device with high electroluminescence efficiency.

It is understood that each functional layer can be made up of more than one layer.

The device can be prepared by a variety of techniques, including sequential vapor deposition of the individual layers on a suitable substrate. Substrates such as glass, plastics, and metals can be used. Conventional vapor deposition techniques can be used, such as thermal evaporation, chemical vapor deposition, and the like. Alternatively, the organic layers can be applied from solutions or dispersions in suitable solvents, using conventional coating or printing techniques, including but not limited to spin-coating, dip-coating, roll-to-roll techniques, ink-jet printing, screen-printing, gravure printing and the like.

The present invention also relates to an electronic device comprising at least one active layer positioned between two electrical contact layers, wherein the at least one active layer of the device includes the anthracene compound of Formula 1. Devices frequently have additional hole transport and electron transport layers.

To achieve a high efficiency LED, the HOMO (highest occupied molecular orbital) of the hole transport material desirably aligns with the work function of the anode, and the LUMO (lowest un-occupied molecular orbital) of the electron transport material desirably aligns with the work function of the cathode. Chemical compatibility and sublimation temperature of the materials are also important considerations in selecting the electron and hole transport materials.

It is understood that the efficiency of devices made with the anthracene compounds described herein, can be further improved by optimizing the other layers in the device. For example, more efficient cathodes such as Ca, Ba or LiF can be used. Shaped substrates and novel hole transport materials that result in a reduction in operating voltage or increase quantum efficiency are also applicable. Additional layers can also be added to tailor the energy levels of the various layers and facilitate electroluminescence.

The compounds of the invention often are fluorescent and photoluminescent and can be useful in applications other than OLEDs, such as oxygen sensitive indicators and as fluorescent indicators in is bioassays.

### EXAMPLES

The following examples illustrate certain features and advantages of the present invention. They are intended to be illustrative of the invention, but not limiting. All percentages are by weight, unless otherwise indicated.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described to herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

1. An electroactive composition comprising an anthracene derivative host and an electroluminescent material, wherein the anthracene derivative host has Formula I(a): 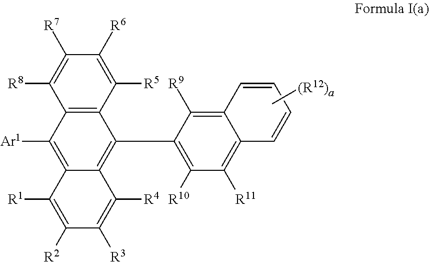
where:
Ar¹ is an aryl group;
R¹ through R⁸ and R¹¹ are the same or different and are selected from the group consisting of H, D, alkyl, silyl, and aryl;
R⁹ and R¹⁰ are the same or different and are selected from the group consisting of H, D, and C₁₋₅ alkyl, with the proviso that at least one of R⁹ and R¹⁰ is alkyl or silyl;
R¹² is the same or different at each occurrence and is selected from the group consisting of D, alkyl, silyl, and aryl; and
a is an integer from 0 to 4;
or Formula I(b): 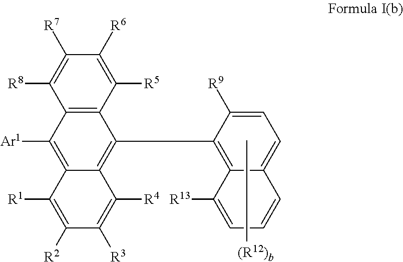
where:
Ar¹ is an aryl group;
R¹ through R⁸ and R¹¹ are the same or different and are selected from the group consisting of H, D, alkyl, alkoxy, aryl, aryloxy, silyl, and siloxane;
R⁹ and R¹³ are the same or different and are selected from the group consisting of H, D, and C₁₋₅ alkyl, with the proviso that at least one of R⁹ and R¹³ is alkyl or silyl;
R¹² is the same or different at each occurrence and is selected from the group consisting of D, alkyl, silyl, and aryl; and
b is an integer from 0 to 5.

2. The composition of claim 1, wherein Ar¹ is selected from the group consisting of phenyl, naphthyl, phenanthryl, anthracenyl, phenylnaphthylene, naphthylphenylene, deuterated analogs thereof, and a group having Formula II: 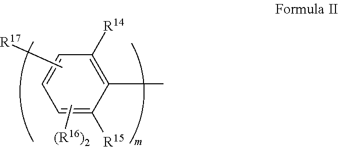
where:
R¹⁴ and R¹⁵ are the same or different and are selected from the group consisting of H, D, and C₁₋₅ alkyl;
R¹⁶ is the same or different at each occurrence and is selected from the group consisting of H, D, alkyl, alkoxy, siloxane and silyl, or adjacent R¹⁶ groups may be joined together to form an aromatic ring;
R¹⁷ is selected from the group consisting of H, D, alkyl, silyl, and aryl; and
m is the same or different at each occurrence and is an integer from 1 to 6.

3. The composition of claim 1, wherein R¹ through R⁸ are selected from H and D.

4. The composition of claim 1, wherein at least one of R¹ through R⁸ is selected from alkyl, alkoxy, aryl, aryloxy, siloxane, and silyl, and the remainder of R¹ through R⁸ are selected from H and D.

5. The composition of claim 1, wherein at least one R¹² is an aryl group.

6. The composition of claim 5, wherein at least one R¹² is selected from the group consisting of phenyl, naphthyl, phenanthryl, anthracenyl, and deuterated analogs thereof.

7. The composition of claim 1, wherein the electroluminescent dopant is selected from the group consisting of amino-substituted chrysenes and amino-substituted anthracenes.

8. An organic electronic device comprising an anode, a cathode, and an electroactive layer therebetween, wherein the electroactive layer comprises the electroactive composition of claim 1.

9. An anthracene derivative compound having Formula I(a): 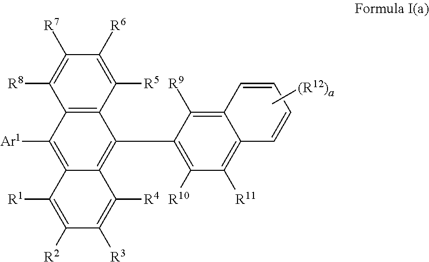
where:
Ar¹ is an aryl group;
R¹ through R⁸ and R¹¹ are the same or different and are selected from the group consisting of H, D, alkyl, silyl, and aryl;
R⁹ and R¹⁰ are the same or different and are selected from the group consisting of H, D, and C₁₋₅ alkyl, with the proviso that at least one of R⁹ and R¹⁰ is alkyl or silyl;
R¹² is the same or different at each occurrence and is selected from the group consisting of D, alkyl, silyl, and aryl; and
a is an integer from 0 to 4;
or Formula I(b): 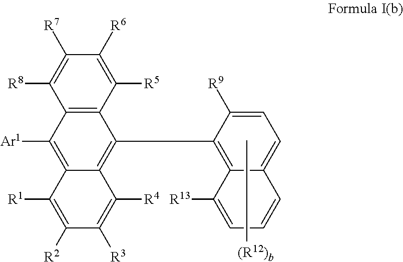
where:
Ar¹ is an aryl group;
R¹ through R⁸ and R¹¹ are the same or different and are selected from the group consisting of H, D, alkyl, alkoxy, aryl, aryloxy, silyl, and siloxane;
R⁹ and R¹³ are the same or different and are selected from the group consisting of H, D, and C₁₋₅ alkyl, with the proviso that at least one of R⁹ and R¹³ is alkyl or silyl;
R¹² is the same or different at each occurrence and is selected from the group consisting of D, alkyl, silyl, and aryl; and
b is an integer from 0 to 5;
wherein the compound is at least 50% deuterated.
